(19) United States
(12) Patent Application Publication
(10) Pub. No.: US 2015/0163929 A1
(43) Pub. Date: Jun. 11, 2015

(54) ELECTRONIC DEVICE WITH HANDLE MECHANISM

(71) Applicants: Hon Hai Precision Industry Co., Ltd., New Taipei (TW); Fu Tai Hua Industry (Shenzhen) Co., Ltd., Shenzhen (CN)

(72) Inventor: CHUAN WANG, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 14/197,360

(22) Filed: Mar. 5, 2014

(30) Foreign Application Priority Data
Dec. 5, 2013 (CN) 2013106437648

(51) Int. Cl. H05K 5/02; H05K 5/00

(52) U.S. Cl. CPC H05K 5/023; H05K 5/0217; H05K 5/0086

(57) ABSTRACT

An electronic device includes a main body and a handle mechanism fixed to the main body. The handle mechanism includes a pair of sliding blocks placed on a bottom of the main body, and each defining a sliding track, a pair of sliding poles slidably received into the sliding tracks, and a handle fixed to a first end of the two sliding poles. The handle is movable to drive the two sliding poles to slide along the two sliding tracks towards an orientation away from the main body until a second end of the two sliding poles is resisted by a sidewall of the main body.

### BACKGROUND

1. Technical Field

The present disclosure relates to electronic devices, and particularly to an electronic device with a handle mechanism.

2. Description of Related Art

To move an electronic device to different positions, a force is applied to grip the electronic device manually and to move it. However, if a surface of the electronic device is smooth, it is difficult for a hand to grip and move it to different positions.

Therefore, what is needed is an electronic device with a handle mechanism to overcome the above described limitations.

### BRIEF DESCRIPTION OF THE DRAWING

FIG. 1 is an isometric view of an embodiment of an electronic device.

FIG. 2 is a partial isometric view of the electronic device of FIG. 1.

FIG. 3 is a cross-sectional view of the electronic device of FIG. 1.

FIG. 4 is an enlarged view of an end portion of a sliding pole of the electronic device of FIG. 1.

FIG. 5 is a cross-sectional of the electronic device in a using state.

### DETAILED DESCRIPTION

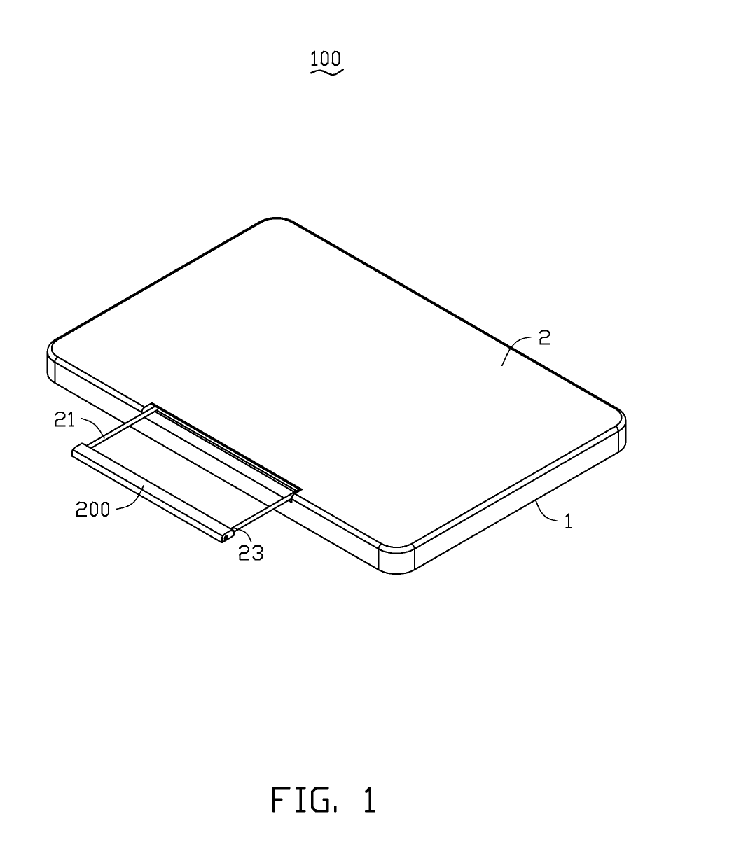

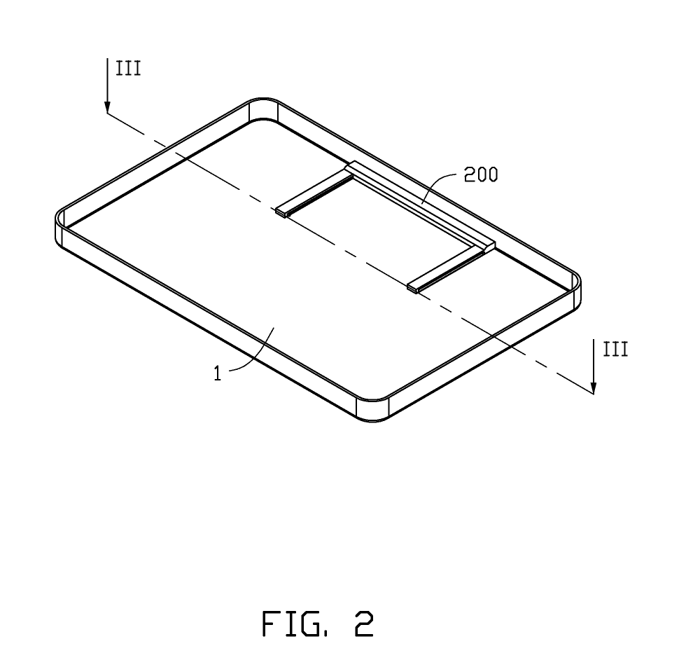

FIGS. 1-3 show an embodiment of an electronic device 100 with a handle mechanism. The electronic device 100 includes a main body 1, a cover 2 engaged on the main body 1, and a handle mechanism 200 fixed to the main body 1.

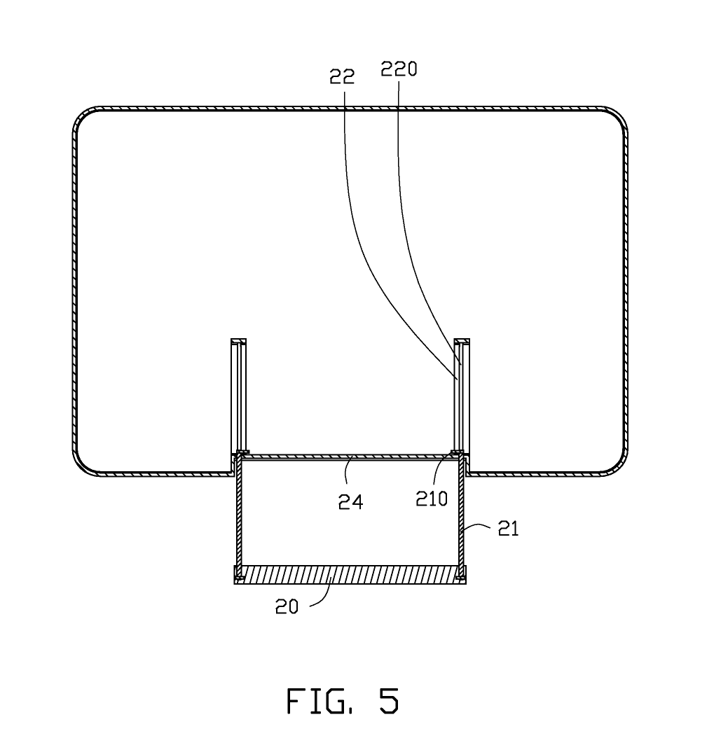

The handle mechanism 200 includes a pair of sliding blocks 22 placed on a bottom of the main body 1, a pair of sliding poles 21, and a handle 20. Each sliding pole 21 includes a first end 23 and a second end 211. Each sliding block 22 defines a sliding track 220 (shown in FIG. 5). Each sliding pole 21 is movably received into the sliding track 220. The handle 20 is fixed to the first end 23 of the two sliding poles 21.

When lifting the electronic device 100, an external force is applied to the handle 20 to drive the sliding poles 21 to slide along the sliding track 220 away from the main body 1 until the second end 211 of the two sliding poles 21 is resisted by the sidewall 101 of the main body 1.

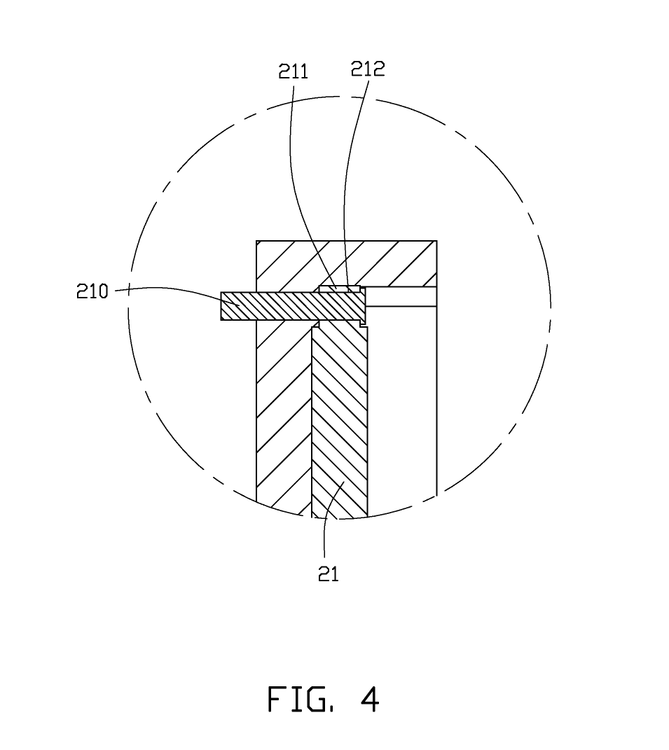

FIG. 4 shows that the second end 211 of each sliding pole 21 defines a through hole 212 along a direction which is substantially perpendicular to a lengthwise direction of the sliding pole 21.

The handle mechanism 200 further includes a pair of resisting blocks 210. A portion of each resisting block 210 is fixedly received into the through hole 212. A remaining portion of each resisting block 210 is engaged with the sidewall 101 of the main body 10 to stop the two sliding poles 21 from sliding out of the sliding tracks 220 when the handle 20 is lifted upward by the external force.

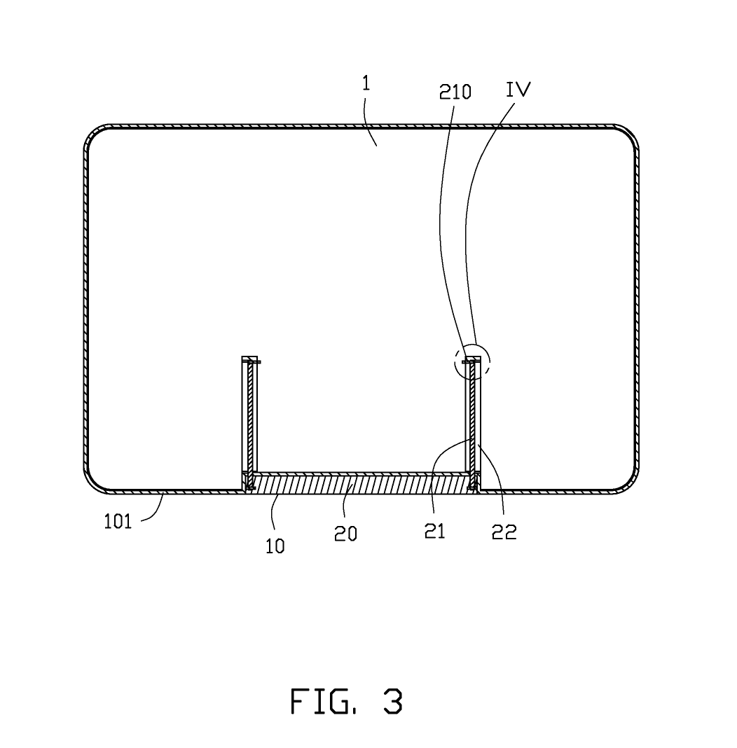

FIGS. 3 and 5 shows that a receiving portion 10 is defined in a middle position of the sidewall 101 of the main body 1. The receiving portion 10 is used to receive the handle 20 when the sliding poles 21 are completely received into the sliding tracks 220.

When carrying the electronic device 100, the external force is applied to the handle 20 to drive the sliding poles 21 to horizontally slide away from the main body along the sliding track 220 until the resisting blocks 210 are resisted by the sidewall 101 of the electronic device 200, thereby stopping the sliding poles 21 from sliding out of the sliding blocks 22. The user can then lift up the handle 20 to move the electronic device 100. After the electronic device 100 is moved to a predetermined position and the electronic device 100 is horizontally placed on a desktop, another external force is applied to the handle 20 to push the sliding poles 21 to sliding along the sliding track 220 until the handle 20 is completely received into the receiving portion 10.

Although various embodiments have been specifically described, the disclosure is not to be construed as being limited thereto. Various changes or modifications may be made to the embodiments without departing from the scope and spirit of the disclosure.

What is claimed is:

1. An electronic device comprising a main body and a handle mechanism fixed to the main body, the handle mechanism comprising:
a pair of sliding blocks placed on a bottom of the main body, and each defining a sliding track;
a pair of sliding poles slidably received into the sliding tracks; and
a handle fixed to a first end of the two sliding poles;
wherein the handle is movable to drive the two sliding poles to slide along the two sliding tracks until a second end of the two sliding poles is resisted by a sidewall of the main body.

2. The electronic device as described in claim 1, wherein the second end of each sliding pole defines a through hole substantially perpendicular to a lengthwise orientation of the sliding pole, the handle mechanism further comprises a pair of resisting blocks, a portion of each resisting block is fixedly received into the through hole, a remaining portion of each resisting block is configured to engage with the sidewall of the main body to prevent the two sliding poles from sliding out of the sliding tracks.

3. The electronic device as described in claim 1, wherein the sidewall of the main body defines a receiving portion in a middle position thereof, and the receiving portion receives the handle when the two sliding poles are completely received into the two sliding tracks.
